(19) United States
(12) Patent Application Publication
(10) Pub. No.: US 2026/0060021 A1
(43) Pub. Date: Feb. 26, 2026

(54) Method for Stripping Organic Material and Residue from Semiconductor Integrated Circuit

(71) Applicant: International Business Machines Corporation, Armonk, NY (US)

(72) Inventors: Luxherta Buzi, Chappaqua, NY (US); Lynne Marie Gignac, Beacon, NY (US); John Bruley, Poughkeepsie, NY (US)

(21) Appl. No.: 18/810,705

(22) Filed: Aug. 21, 2024

(51) Int. Cl. H01L 21/311; H01L 21/768

(52) U.S. Cl. CPC H01L 21/31138; H01L 21/76802; H01L 21/7684; H01L 21/76877

(57) ABSTRACT

A method for fabricating an integrated circuit (IC) includes forming a silicon substrate and doping the silicon substrate with impurities. The method includes sequentially depositing and patterning multiple layers over the silicon substrate, wherein the layers comprise at least a dielectric layer, a metallization layer, an organic polarized layer (OPL), and a photoresist layer. The method includes etching one or more of the layers to create features including vias or trenches. The method includes cooling the IC to a temperature of around 20° C. or lower. The method includes stripping at least the organic planarization layer (OPL) and photoresist residue using ammonia (NH3) plasma to expose the metallization layer and depositing a metal in the vias or trenches.

### BACKGROUND

The present disclosure relates generally to semiconductor fabrication, and more specifically to a method for stripping organic material and residue from semiconductor integrated circuits.

Semiconductor integrated circuits (ICs) are fabricated using a process which includes the sequential depositing and patterning of various layers on a silicon substrate. These layers typically include one or more dielectric layers, polysilicon layers, metallization layers, Organic Planarization Layers (OPL), and other functional layers.

The fabrication process begins with a high-purity silicon wafer, which acts as the foundation for an IC. The dielectric layers, polysilicon layers, metallization layers, OPL, and other functional layers are sequentially deposited and patterned over the silicon substrate.

To complete functional circuits and electrically connect a metallization layer to upper layers such as, for example, a back end of line (BEOL), vias and trenches are etched through different layers of the IC. The vias and trenches are then filled with metal (e.g., copper). Typically, a photoresist layer is deposited on top of the OPL. The photoresist layer is exposed to light through a photomask, which defines patterns (e.g., vias and trenches) to be etched into the underlying layers. The exposed (or unexposed, depending on whether the photoresist layer is a positive or negative photoresist) areas are then developed away, leaving the pattern for etching.

Next, etching processes (e.g., wet or dry) are used to remove (strip) material from areas of the different layers defined by the pattern. During the stripping process which involves high temperature, the copper layer can experience thermal stress. Copper has a relatively high coefficient of thermal expansion, and under thermal stress, copper can expand unevenly, leading to the formation of hillocks. Also, when oxygen is used in the stripping process, it reacts with the exposed copper layer, leading to the formation of copper oxides. These oxides can cause stresses in the copper layer, further contributing to the formation of hillocks.

Formation of copper hillocks during the stripping process can lead to several problems, affecting the performance and reliability of the IC. Copper hillocks can grow large enough to protrude into adjacent layers or make contact with other metal lines or vias, creating unintended electrical connections, leading to short circuits. Also, copper hillocks can cause irregularities in the copper interconnects, leading to higher electrical resistance in the affected areas. Higher resistance in the interconnects can degrade signal integrity, slow down the circuit operation, and increase power consumption. Also, copper hillocks can penetrate or deform the insulating dielectric layers that separate the metallization layers. This can reduce the dielectric integrity, leading to increased leakage currents or dielectric breakdown. Also, the presence of copper hillocks can lead to defects in multiple chips on a wafer, reducing the overall yield of the manufacturing process.

### SUMMARY

Illustrative embodiments provide a method for fabricating an integrated circuit (IC). The method includes forming a silicon substrate and sequentially depositing and patterning multiple layers over the silicon substrate. The layers include at least a dielectric layer, a metallization layer, an organic planarization layer (OPL), and a photoresist layer. The method includes etching one or more of the layers to create features including vias or trenches. The method includes cooling the IC to a temperature of around 20° C. or lower. The method includes stripping at least the organic polarized layer (OPL) and photoresist residue using ammonia (NH₃) plasma to expose the metallization layer. The method includes depositing a metal in the vias or trenches. The metal can be copper (Cu), tungsten (W), aluminum (Al), titanium nitride (TiN) or tantalum nitride (TaN). The method includes removing excess metal from the surface of the IC using chemical mechanical planarization (CMP). The stripping using the ammonia (NH₃) plasma causes the formation of a passivating layer on the metallization layer.

### BRIEF DESCRIPTION OF THE DRAWINGS

FIG. 1 illustrates a cross-sectional view of a semiconductor IC fabricated in accordance with an illustrative embodiment.

FIG. 2 illustrates the IC from which a photoresist layer is removed.

FIGS. 3-5 illustrate further processing of the IC in accordance with illustrative embodiments.

FIG. 6 is a flowchart of a method for IC fabrication in accordance with an illustrative embodiment.

FIG. 7 illustrates an example of a copper hillock.

FIG. 8 illustrates an image of an IC fabricated in accordance with the illustrative embodiments.

### DETAILED DESCRIPTION

The illustrative embodiments address limitations of existing semiconductor integrated circuit (IC) fabrication processes. The illustrative embodiments provide a method of removing (stripping) organic material and photoresist residue while reducing formation of copper hillocks.

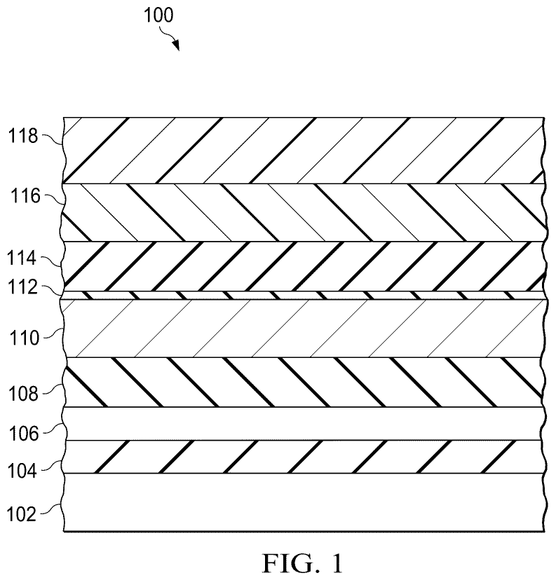

FIG. 1 illustrates a cross-sectional view of semiconductor IC 100 fabricated in accordance with an illustrative embodiment. The fabrication process begins with silicon wafer 102, which acts as the foundation for building electronic devices (e.g., transistors, diodes, capacitors). Next, gate dielectric layer 104 is deposited on top of silicon wafer 102. Gate dielectric layer 104 can be formed with silicon nitride (SiN) or silicon dioxide (SiO₂) using thermal oxidation, where silicon wafer 102 is exposed to oxygen at high temperatures, or through chemical vapor deposition (CVD). Gate dielectric layer 104 acts as an insulating layer for electronic devices (e.g., transistors, diodes, capacitors).

Next, polysilicon gate layer 106 is deposited on top of gate dielectric layer 104 using CVD. Polysilicon gate layer 106 can be patterned (not shown in FIG. 1) to form gates of the transistors. Next, Interlayer Dielectric (ILD) 108 is deposited over polysilicon gate layer 106. ILD 108 can be formed with silicon dioxide or a low-k dielectric using techniques such as CVD or spin coating. ILD 108 insulates different parts of circuits and serves as a base for interconnects. In some embodiments, IC 100 may include multiple levels of ILDs.

Next, first metallization layer (e.g., copper layer or tungsten layer) 110 is deposited on top of ILD 108. First metallization layer 110 can be deposited using electrochemical plating, where copper ions or tungsten ions are deposited. In some example embodiments, etch stop layer 112 (e.g., SiN) can be deposited on top of first metallization layer 110. Etch stop layer 112 is used to control the depth of etches and prevent over-etching into underlying layers.

Additional levels of ILDs 114 for multilevel interconnects can be deposited to prepare for subsequent metallization layers. This process can be repeated for each metallization level, with each level separated by dielectric layers.

Next, Organic Planarization Layer (OPL) 116 is deposited over the ILD layers using spin coating to create a thin, uniform layer. OPL 116 is used to enhance the lithographic patterning process and improve the adhesion between various layers during fabrication. OPL 116 can provide a planarizing effect, smoothing out surface irregularities before the application of other layers (e.g., photoresist layer), leading to better pattern transfer. OPL 116 is typically composed of organic materials, often polymers, that can bond effectively with both the underlying dielectric layers and photoresist layers.

Next, photoresist layer 118 is deposited on top of OPL 114 using spin coating. Photoresist layer 118 is made from a light-sensitive material used in the photolithography process. The material in photoresist layer 118 is typically a complex organic polymer that changes its solubility in a developer solution when exposed to light. Photoresist layer 118 is exposed to light through a photomask (not shown in FIG. 1), which defines patterns to be etched into the underlying layers. The exposed photoresist layer or unexposed photoresist layer, depending on whether the photoresist layer is a positive or a negative photoresist, is then removed (stripped), leaving a pattern for etching or deposition. Vertical interconnects (vias) and trenches can be formed in areas defined by the pattern to create conductive paths to metallization layer 110.

In other embodiments, the IC can be fabricated with fewer or more number of layers including other types of layers (not shown in FIG. 1).

In IC 100, additional layers (e.g., upper layers) can be added later. These upper layers may include metallization layers and ILDs.

During the process of stripping organic materials and photoresist residue which involves high temperature, the metallization layer (e.g., copper layer) can expand unevenly, leading to the formation of copper hillocks. Also, when oxygen is used in the stripping, it reacts with the exposed copper layer, leading to the formation of copper oxides. These oxides can cause stresses in the copper layer, further contributing to the formation of copper hillocks. Formation of copper hillocks during the stripping process can lead to several problems, affecting both the performance and reliability of the ICs.

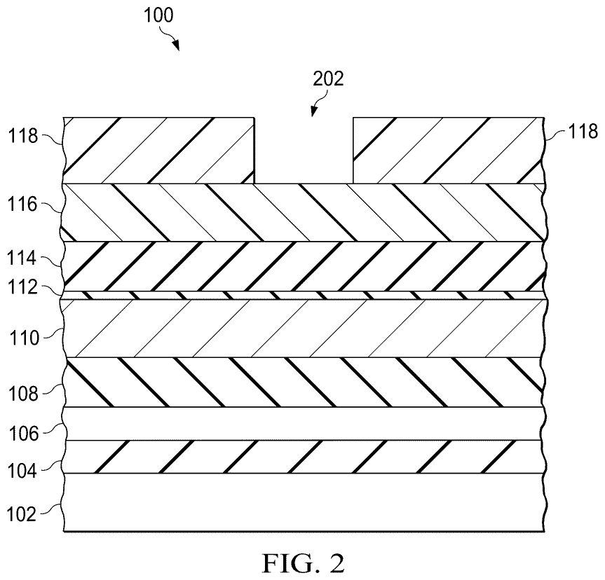

The illustrative embodiments address limitations of semiconductor IC fabrication processes by reducing the formation of copper hillocks. FIG. 2 illustrates IC 100, of which photoresist layer 118 is exposed to light through a photomask (not shown in FIG. 2), which defines patterns to be etched into the underlying layers. The exposed (or unexposed, depending on whether the photoresist layer is a positive or negative photoresist) area 202 of photoresist layer 118 is removed (stripped), leaving the pattern for etching. The removal can be accomplished by dry stripping using oxygen plasma to oxidize and break down photoresist layer 118 into volatile compounds, which are then removed by vacuum (e.g., using a pump). As a result of the removal of section 202 of photoresist layer 116, OPL layer 116 is exposed.

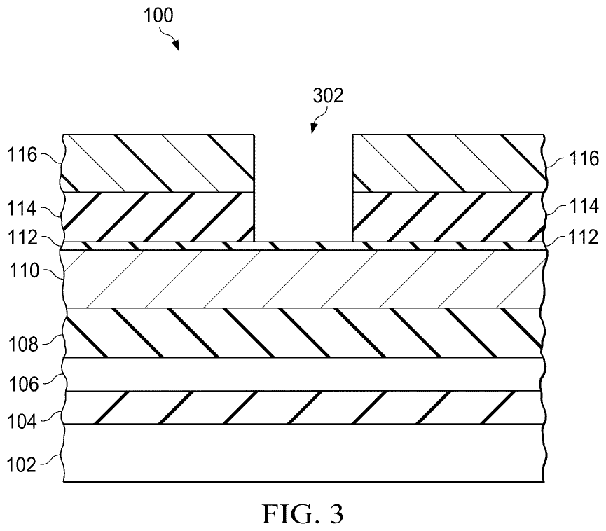

FIG. 3 illustrates further processing of IC 100 in accordance with an illustrative embodiment. The remaining photoresist layer is removed from IC 100.

Next, etching processes are used to create features such as via 302 which is used to connect different metallization layers in IC 100. Via 302 is a small hole which connects one layer of metal to another, allowing electrical signals to pass between different levels of IC 100. The etching process is typically carried out using reactive ion etching or anisotropic etching. In some embodiments, etch stop layer 112 (e.g., SiN) is used to precisely control the depth of the etch and prevent over-etching into underlying layers.

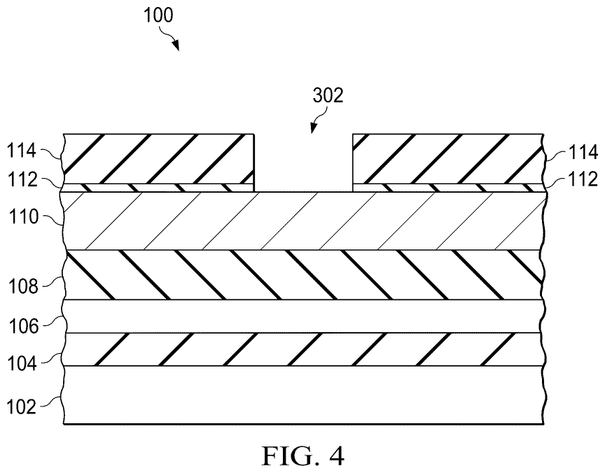

FIG. 4 illustrates further processing of IC 100 in accordance with an illustrative embodiment. In this stage, IC 100 is cooled to a low temperature. In an example embodiment, IC 100 is cooled to a low temperature of around 20° C. or lower. After IC 100 is cooled to this temperature, ammonia (NH₃) plasma is used to strip OPL 114 and photoresist residues. In an example embodiment, IC 100 is maintained at the low temperature (e.g., 20 degrees C.) while OPL 114 and photoresist residues are stripped. In some embodiments, the process involves exposing IC 100 to an ammonia plasma which reacts with organic materials or residues to break them down into volatile byproducts that can be removed by vacuum. Ammonia plasma cleans or strips away OPL 116 and photoresist residues, without damaging underlying structures.

Because IC 100 is cooled to a low temperature, the reactivity of the ammonia plasma is better controlled, allowing for a more uniform etch. This ensures that trenches and vias have well-defined vertical profiles. Also, because IC 100 is cooled to 20 degree C. or lower, the risk of thermal damage to IC 100 is minimized.

Furthermore, the method of cooling IC 100 to a low temperature (e.g., 20 degree C. or lower) and using ammonia plasma stripping is particularly effective in minimizing the formation of copper hillocks. Keeping IC 100 at a low temperature during the stripping process minimizes diffusion and the associated stress, reducing the likelihood of copper hillock formation. Also, ammonia plasma has relatively gentle etching properties compared to more aggressive chemicals. This gentler etch minimizes mechanical stress on the underlying copper layer, which can otherwise contribute to copper hillock formation. Also, ammonia plasma can contribute to the formation of a passivating layer (e.g., copper nitride Cu3N) on the surface of the copper. This passivating layer (CuN3) helps to prevent unwanted reactions that could lead to the growth of copper hillocks. The passivating layer can also act as an etch stop layer.

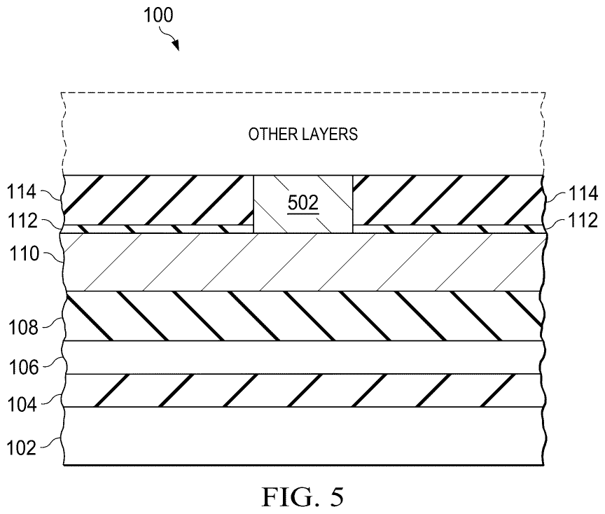

FIG. 5 illustrates further processing of IC 100 in accordance with an illustrative embodiment. In this example, metal 502 (e.g., copper) is deposited in the via to create conductive paths between different layers of IC 100. The other layers may include global interconnects and global rails (e.g., power supply rails. The metal fill process can be carried out using deposition. After the metal fill process, chemical mechanical planarization (CMP) can be used to remove excess copper from the surface of IC 100, leaving copper only in the via. In other example embodiments, metal 502 can be tungsten (W), aluminum (Al), titanium nitride (TiN) or tantalum nitride (TaN).

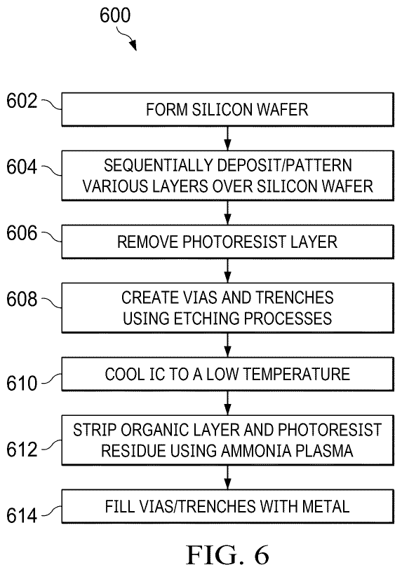

With reference next to FIG. 6, a flowchart of process 600 for a method for semiconductor IC fabrication is provided. Process 600 begins at block 602 in which a silicon substrate or wafer is formed. The silicon substrate or wafer acts as the foundation for building electronic devices (e.g., transistors, diodes, capacitors).

At block 604 various layers, such as, for example, dielectric layer, polysilicon layer, metallization layer, Organic Planarized Layer (OPL), photoresist layer, and other functional layers are sequentially deposited and patterned over the silicon substrate.

At block 608, etching processes are used to create features such as vias and trenches which are used to connect different layers in the IC. At block 610, the IC is cooled to a low temperature. In an example embodiment, the IC is cooled to a low temperature of around 20° C. or lower.

At block 612, after the IC is cooled to a low temperature, ammonia (NH₃) plasma is used to strip an OPL layer and photoresist residue to expose a metallization layer.

At block 614, metal (e.g., copper) is deposited in the vias and/or trenches to create conductive paths between different layers of the IC. The metal fill process can be carried out using deposition. After the metal fill process, chemical mechanical planarization (CMP) can be used to remove excess metal from the surface of the IC.

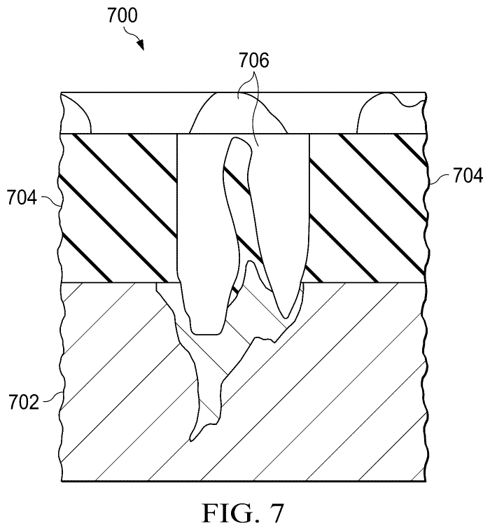

FIG. 7 illustrates an example of a copper hillock. IC 700 includes copper layer 702 and dielectric layer 704. Via 706 is etched in IC 700 through dielectric layer 704 to expose copper layer 702. In FIG. 7, copper hillock 706 can form during stripping of the organic layer and photoresist residue.

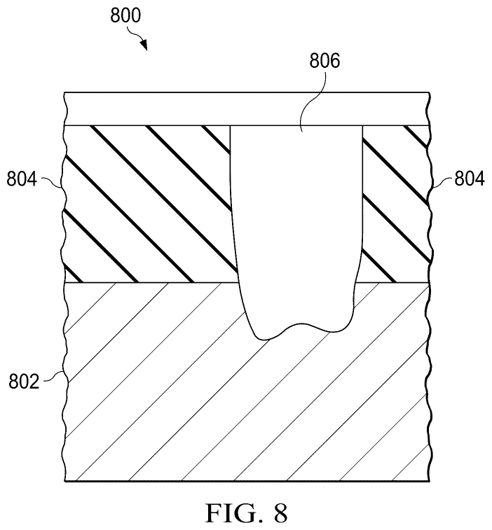

FIG. 8 illustrates an image of IC 800 fabricated in accordance with the illustrative embodiments. IC 800 includes copper layer 802 and dielectric layer 804. Via 806 is etched in IC 800 through dielectric layer 804 to expose copper layer 802. In FIG. 8, in accordance with the illustrative embodiments, organic layer and photoresist residue was stripped using ammonia plasma after IC 800 was cooled to a low temperature (e.g., 20 degree C.). As a result, copper hillocks did not form in IC 800.

As used herein, “a number of,” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The different illustrative examples describe components that perform actions or operations. In an illustrative embodiment, a component may be configured to perform the action or operation described. For example, the component may have a configuration or design for a structure that provides the component an ability to perform the action or operation that is described in the illustrative examples as being performed by the component.

Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A method for fabricating an integrated circuit (IC) comprising:
forming a silicon substrate;
sequentially depositing and patterning multiple layers over the silicon substrate, wherein the layers comprise at least a dielectric layer, a metallization layer, an organic planarization layer (OPL), and a photoresist layer;
etching one or more of the layers to create features including vias or trenches;
cooling the IC to a temperature of around 20°C. or lower;
stripping at least the organic polarized layer (OPL) and photoresist residue using ammonia (NH₃) plasma to expose the metallization layer; and
depositing a metal in the vias or trenches.

2. The method of claim 1, wherein the layers comprise a polysilicon layer.

3. The method of claim 1, further comprising depositing the metal in the vias or trenches to create conductive paths between different layers of the IC using a deposition process.

4. The method of claim 1, further comprising removing excess metal from the surface of the IC using chemical mechanical planarization (CMP).

5. The method of claim 1, wherein the metal deposited in the vias or trenches is copper.

6. The method of claim 1, wherein the IC is cooled to a temperature of 20°C. or lower before stripping at least the organic planarization layer (OPL) and photoresist residue using the ammonia (NH₃) plasma.

7. The method of claim 1, wherein the stripping using the ammonia (NH₃) plasma causes the formation of a passivating layer on the metallization layer.

8. The method of claim 7, wherein the passivating layer is a layer of copper nitride (Cu3N).

9. A method for fabricating an integrated circuit (IC) comprising:
forming a silicon substrate;
sequentially depositing and patterning multiple layers over the silicon substrate, wherein the layers comprise at least a dielectric layer, a copper layer, an organic planarization layer (OPL), and a photoresist layer;
etching one or more of the layers to create features including vias or trenches;
cooling the IC to a temperature of around 20°C. or lower;
stripping at least the organic polarized layer (OPL) and photoresist residue using ammonia (NH₃) plasma to expose the copper layer, wherein the stripping using the ammonia (NH₃) plasma causes the formation of a copper nitride layer over the metallization layer; and
depositing a metal in the vias or trenches.

10. The method of claim 9, wherein the layers comprise a polysilicon layer.

11. The method of claim 9, further comprising removing excess metal from the surface of the IC using chemical mechanical planarization (CMP).

12. The method of claim 9, wherein the metal deposited in the vias or trenches is copper.

13. The method of claim 9, wherein the IC is cooled to a temperature of 20°C. or lower before stripping at least the organic planarization layer (OPL) and photoresist residue using the ammonia (NH₃) plasma.

14. The method of claim 13, wherein the IC is maintained at the temperature of 20°C. or lower during the stripping of at least the organic planarization layer (OPL) and photoresist residue using the ammonia (NH₃) plasma.

15. A method for fabricating an integrated circuit (IC) comprising:
forming a silicon substrate;
sequentially depositing and patterning multiple layers over the silicon substrate, wherein the layers comprise at least a dielectric layer, a metallization layer, an organic planarization layer (OPL), and a photoresist layer;
etching one or more of the layers in areas defined by a pattern to create features including vias or trenches;
cooling the IC to a temperature of around 20°C. or lower;
stripping at least the organic planarization layer (OPL) and photoresist residue using ammonia (NH₃) plasma to expose the metallization layer, wherein the stripping using the ammonia (NH₃) plasma causes the formation of a passivating layer over the metallization layer; and
depositing a metal in the vias or trenches.

16. The method of claim 15, wherein the metallization layer is a copper layer.

17. The method of claim 15, wherein the passivating layer is a copper nitride (Cu3N) layer.

18. The method of claim 15, wherein the metal deposited in the vias or trenches is copper.

19. The method of claim 15, wherein the metal deposited in the vias or trenches is aluminum, tungsten, titanium nitride or tantalum nitride.

20. The method of claim 15, wherein the IC is maintained at the temperature of 20°C. or lower during the stripping of at least the organic planarization layer (OPL) and photoresist residue using the ammonia (NH₃) plasma.
